(19) United States
(12) Patent Application Publication
(10) Pub. No.: US 2026/0214876 A1
(43) Pub. Date: Jul. 23, 2026

(54) INTEGRATED CIRCUIT

(71) Applicant: Taiwan Semiconductor Manufacturing Company, Ltd., Hsinchu (TW)

(72) Inventor: Jhon Jhy Liaw, Hsinchu County (TW)

(73) Assignee: Taiwan Semiconductor Manufacturing Company, Ltd., Hsinchu (TW)

(21) Appl. No.: 19/035,772

(22) Filed: Jan. 23, 2025

(51) Int. Cl. H10B 10/00; G11C 11/412; G11C 11/419

(52) U.S. Cl. CPC H10B 10/12; G11C 11/412; G11C 11/419

(57) ABSTRACT

An integrated circuit is provided. The integrated circuit includes memory cells, respectively comprising an inverter and two pass-gate transistors coupled to two data nodes of the inverter; pairs of bit lines, passing through the memory cells from above the memory cells, and coupled to the data nodes through the pass-gate transistors, wherein each memory cell is intersected with a single one of the bit lines, and connected to the intersected one of the bit lines as well as another one of the bit lines passing through an adjacent one of the memory cells; and a power distribution network, powering the memory cells from below the memory cells.

### BACKGROUND

At advanced technology node, embedded static random access memory (SRAM) is comprehensively used as cache memory in high speed communication, image processing, system-on-chip (SOC) and similar products. However, along with continuous scaling, routing SRAM cells becomes challenging. Further, considering inevitable process variation, certain difference in characteristics between N-type transistors at opposite sides of P-type transistors in each SRAM cell may result in instability to SRAM performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a single cell in a SRAM, according to some embodiments of the present disclosure.

FIG. 2A is a schematic diagram illustrating four SRAM cells arranged along a row direction, according to some embodiments of the present disclosure.

FIG. 2B schematically illustrates an array of SRAM cells, according to some embodiments of the present disclosure.

FIG. 3A includes schematic plan views showing layout design of the adjacent SRAM cells at wafer frontside and wafer backside, according to some embodiments of the present disclosure.

FIG. 3B includes schematic plan views showing metallization tiers next to the ones shown in FIG. 3A, according to some embodiments of the present disclosure.

FIG. 4 includes schematic plan views showing layout design of adjacent SRAM cells at wafer frontside and wafer backside, according to some embodiments of the present disclosure.

FIG. 5A includes schematic plan views showing layout design of adjacent SRAM cells at wafer frontside and wafer backside, according to some embodiments of the present disclosure.

FIG. 5B includes schematic plan views showing layout design of adjacent SRAM cells at wafer frontside and wafer backside, according to some embodiments of the present disclosure.

FIG. 6 includes schematic plan views showing layout design of adjacent SRAM cells at wafer frontside and wafer backside, according to some embodiments of the present disclosure.

FIG. 7 includes schematic plan views showing layout design of adjacent SRAM cells at wafer frontside and wafer backside, according to some embodiments of the present disclosure.

FIG. 8 provides a simplified cross-sectional view showing stacking order of representative ones of layout patterns.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a SRAM with improved routing scheme, and with cell layout that can minimize instability of SRAM performance.

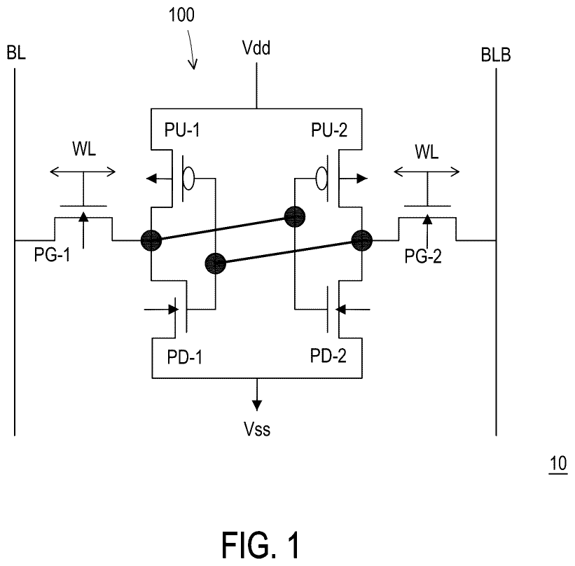

FIG. 1 is a circuit diagram of a single cell 10 in the SRAM, according to some embodiments of the present disclosure.

The SRAM cell 10 includes a latch circuit 100 for securing complementary data at nodes N1, N2. A pass-gate transistor PG-1 coupled to the node N1 controls access to the node N1, whereas a pass-gate transistor PG-2 coupled to the node N2 controls access to the node N2. Data can be written to or read out from the nodes N1, N2 only if the pass-gate transistors PG-1, PG-2 are turned on.

Specifically, a word line WL is coupled to gate terminals of the pass-gate transistors PG-1, PG-2, to control switching of the pass-gate transistors PG-1, PG-2, thus control access to the nodes N1, N2. The pass-gate transistor PG-1 is coupled to the node N1 via one of its source/drain terminals, whereas the other source/drain terminal of the pass-gate transistor PG-1 is coupled to a first bit line BL. On the other hand, the pass-gate transistor PG-2 is coupled to the node N2 via one of its source/drain terminals, whereas the other source/drain terminal of the pass-gate transistor PG-2 is coupled to a second bit line BLB.

During a write operation, data (e.g., complementary data) is provided to the bit lines BL, BLB and written to the nodes N1, N2 through the pass-gate transistors PG-1, PG-2. During a read operation, the bit lines BL, BLB are pre-charged. When the pass-gate transistors PG-1, PG-2 are switched on, one of the bit lines BL, BLB would be pulled down by the logic low data at one of the nodes N1, N2. By sensing voltage variation on the bit lines BL, BLB, data stored at the nodes N1, N2 can be read out.

The latch circuit 100 includes a first pull-up transistor PU-1 and a first pull-down transistor PD-1 connected to form a first inverter. A common source/drain terminal of the first pull-up transistor PU-1 and the first pull-down transistor PD-1 is coupled to one of the source/drain terminals of the pass-gate transistor PG-1, and defines an input/output of the first inverter. The other source/drain terminal of the first pull-up transistor PU-1 is coupled to a power supply voltage Vdd, whereas the other source/drain terminal of the first pull-down transistor PD-1 is connected to a reference voltage Vss. In addition, gate terminals of the first pull-up transistor PU-1 and the first pull-down transistor PD-1 are connected to each other, to define the other input/output of the first inverter.

Further, the latch circuit 100 also includes a second pull-up transistor PU-2 and a second pull-down transistor PD-2 connected to form a second inverter. A common source/drain terminal of the second pull-up transistor PU-2 and the second pull-down transistor PD-2 is coupled to one of the source/drain terminals of the pass-gate transistor PG-2, and defines an input/output of the second inverter. The other source/drain terminal of the second pull-up transistor PU-2 is coupled to the power supply voltage Vdd, whereas the other source/drain terminal of the second pull-down transistor PD-2 is connected to the reference voltage Vss. In addition, gate terminals of the second pull-up transistor PU-2 and the second pull-down transistor PD-2 are connected to each other, to define the other input/output of the second inverter.

To keep data at the nodes N1, N2 complementary to each other, the first and second inverters are cross-coupled to each other. As an example (but not limited to), the connected gate terminals of the first pull-up transistor PU-1 and the first pull-down transistor PU-2 is functioned as the input of the first inverter and connected to the common source/drain terminal of the second pull-up transistor PU-2 and the second pull-down transistor PD-2 functioned as the output of the second inverter, and the common source/drain terminal of the first pull-up transistor PU-1 and the first pull-down transistor PD-1 is functioned as the output of the first inverter and connected to the linked gate terminals of the second pull-up transistor PU-2 and the second pull-down transistor PD-2 functioned as the input of the second inverter. The node N1 is defined as a connected terminals of the first and second inverters, and is accessed to the pass-gate transistor PG-1 by being coupled to one of the source/drain terminals of the pass-gate transistor PG-1. On the other hand, the node N2 is defined as the other connected terminals of the first and second inverters, and is accessed to the pass-gate transistor PG-2 by being coupled to one of the source/drain terminals of the pass-gate transistor PG-2.

As described, each cell 10 in the SRAM is coupled to a pair of the bit lines BL, BLB. In order to release crowded routing area, the cells 10 in the SRAM are grouped so that each bit line pair is shared by two columns of the cells 10.

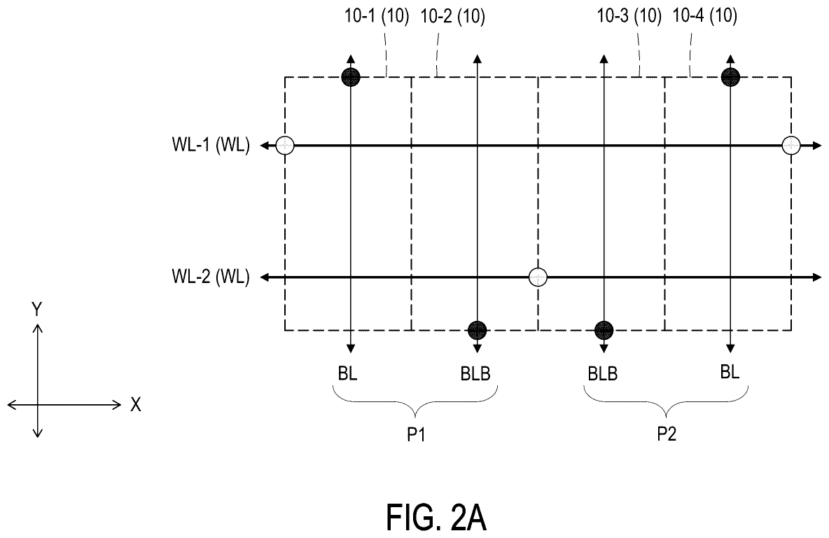

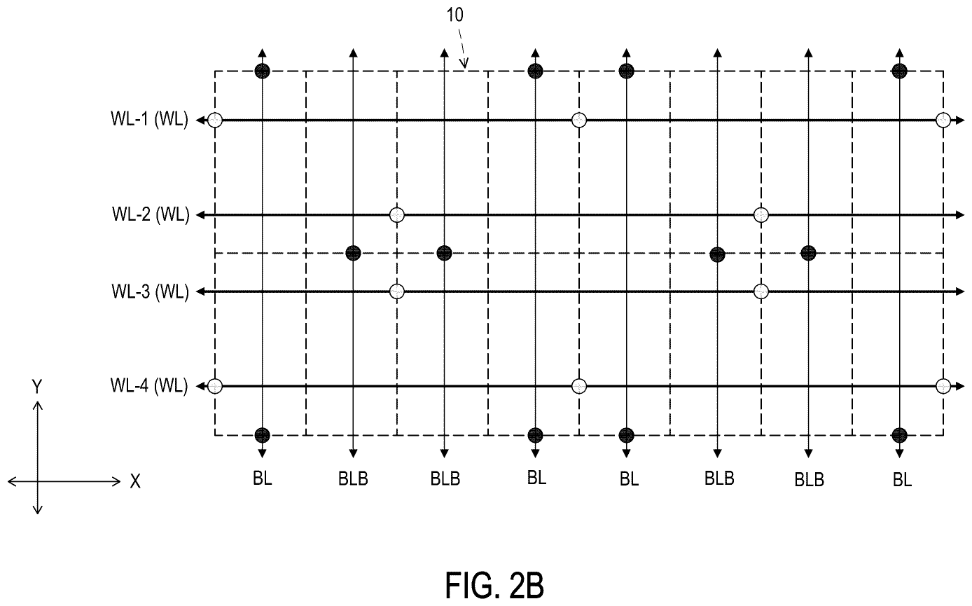

FIG. 2A is a schematic diagram illustrating four of the SRAM cells 10 (referred to as cells 10-1, 10-2, 10-3, 10-4) arranged along a row direction X, according to some embodiments of the present disclosure.

Two of the word lines WL (referred to as word lines WL-1, WL-2) pass through the cells 10-1, 10-2, 10-3, 10-4 along the row direction X. As indicated, the word line WL-1 is coupled to the cells 10-1 and 10-4, whereas the word line WL-2 is coupled to the cells 10-2 and 10-3. Although not depicted, the pass-gate transistors PG-1, PG-2 in the cells 10-1, 10-4 are controlled by the word line WL-1, and the pass-gate transistors PG-1, PG-2 in the cells 10-2, 10-3 are controlled by the word line WL-2.

On the other hand, two pairs of bit lines BL, BLB pass through the cells 10-1, 10-2, 10-3, 10-4 along a column direction Y. Specifically, the bit lines BL, BLB in a first pair P1 pass through the cells 10-1 and 10-2, respectively. In addition, the bit lines BL, BLB in a second pair P2 pass through the cells 10-3 and 10-4, respectively. According to some embodiments, the two pairs of the bit lines BL, BLB are arranged in mirror symmetry with respect to an interface between the cells 10-2 and 10-3. As an example, the bit line BLB in the first pair P1 and the bit line BLB in the second pair P2 are placed along said interface at opposite sides of the interface, whereas the bit line BL in the first pair P1 and the bit line BL in the second pair P2 are placed next to the bit lines BLB, with a spacing from the interface greater than a spacing between the bit lines BLB and the interface.

As will be further described, each pair of the bit lines BL, BLB is shared by two cells 10 next to each other in the row direction X. As an example, the bit lines BL, BLB in the first pair P1 are shared by the cells 10-1 and 10-2. Specifically, the cell 10-1 is coupled to the intersecting bit line BL, and is further connected to the bit line BLB extending aside the cell 10-1 by a lateral contact (not shown). Similarly, the cell 10-2 is coupled to the intersecting bit lie BLB, and is further connected to the bit line BL extending aside the cell 10-2 by a lateral contact (not shown). In this way, each cell 10 is only intersected with one of the connected bit lines BL, BLB. As will be described in greater details, each cell 10 stretches in the column direction Y, and is narrow in the row direction X. If each cell 10 is intersected with a pair of the bit lines BL, BLB arranged along the row direction X, the bit lines BL, BLB deployed in the same metallization tier must be designed with limited line width and limited line spacing. Otherwise, some of the bit lines BL, BLB must be moved to higher metallization tier, and resulted in greater resistance and parasitic capacitance. According to embodiments of the present disclosure, each cell 10 is only intersected with one of the bit lines BL, BLB, therefore the bit lines BL, BLB can be arranged at a low metallization tier (such as the bottom metallization tier, also referred to as M1), with greater line width and greater line spacing. As a consequence, resistance along the bit lines BL, BLB and parasitic capacitance induced along the bit lines BL, BLB can be significantly reduced.

FIG. 2B schematically illustrates an array of the SRAM cells 10, according to some embodiments of the present disclosure.

As indicated, each pair of the bit lines BL, BLB are shared by two columns of the cells 10. In addition, two adjacent pairs of the bit lines BL, BLB are in mirror symmetry with respect to the cell-to-cell interface in between. Further, as will be described with greater detail, adjacent cells 100 arranged along the column direction Y may share contacts to the corresponding pair of the bit lines BL, BLB.

On the other hand, each row of the cells 10 is intersected with two of the word lines WL. As an example, the upper row of the cells 10 shown in the figure is intersected with word lines WL-1, WL-2, and the lower row of the cells 10 shown in the figure is intersected with word lines WL-3, WL-4. Further, the cells 10 in each row are alternately connected to the two intersecting word lines WL by pair. As an example, the cells 10 in the upper row shown in the figure are alternately connected to the word lines WL-1, WL-2 by pair, and each pair of the cells 10 share a contact to the connected word line WL-1/WL-2. Similarly, the cells 10 in the lower row shown in the figure are alternately connected to the word lines WL-3, WL-4 by pair, and each pair of the cells 10 share a contact to the connected word line WL-3/WL-4.

To be connected to the bit lines BL, BLB and the word lines WL by the described manner and to minimize in-cell transistor mismatch, the cells 10 are particularly designed in terms of layout patterns. As will be described in further details, such layout design can result in other benefits.

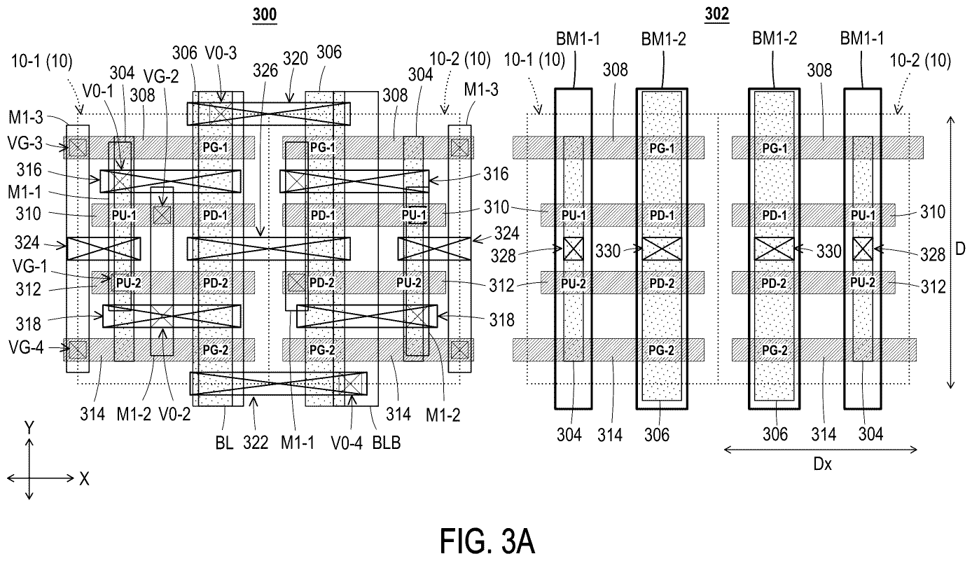

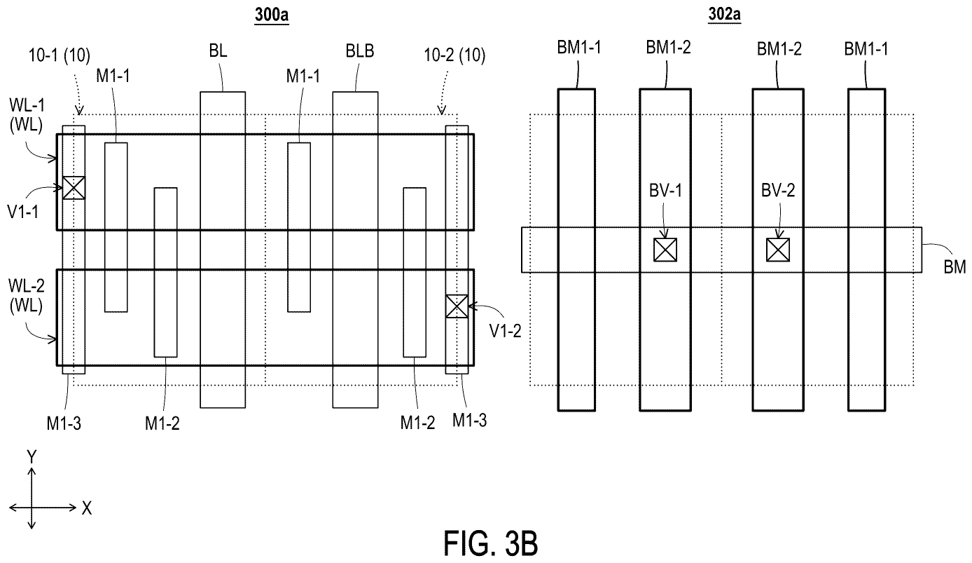

FIG. 3A includes schematic plan views showing layout design of the adjacent SRAM cells 10-1, 10-2 at wafer frontside and wafer backside, according to some embodiments of the present disclosure.

Specifically, a plan view 300 schematically illustrates layout patterns of the adjacent cell 10-1, 10-2 at a frontside of a semiconductor substrate (or referred to as a wafer), whereas a plan view 302 shows layout patterns of the adjacent cells 10-1, 10-2 at a backside of the semiconductor substrate. Nonetheless, active structures 304, 306 and gate patterns 308, 310, 312, 314 formed on the frontside of the semiconductor substrate are also shown in the backside plan view 302, to specify relationship between the layout patterns at the backside of the semiconductor substrate and the layout patterns at the frontside of the semiconductor substrate.

In either the cell 10-1 or the cell 10-2, the active structures 304, 306 separately extend along the column direction Y. The active structure 304 is formed on an N-type well in the semiconductor substrate (not specifically depicted), and provide channel structures for P-type transistors. On the other hand, the active structure 306 is formed on a P-type well (or P-type region) in the semiconductor substrate, and provide channel structures for N-type transistors. According to some embodiments, the channel structures in the active structures 304, 306 are vertically stacked on the semiconductor substrate, and extend along the column direction Y.

The gate structures 308, 310, 312, 314 separately extend along the row direction X, and are arranged in order along the column direction Y. In this way, at wafer frontside, the active structures 304, 306 are covered and intersected with the gate structures 308, 310, 312, 314. Specifically, the channel structures in the active structures 304, 306 are intersected with and wrapped all around by the gate structures 308, 310, 312, 314, to ensure better gate control. N-type transistors are defined at intersections of the active structure 306 and the gate structures 308, 310, 312, 314; whereas P-type transistors are defined at intersections of the active structure 304 and the gate structures 308, 310, 312, 314.

Among the N-type transistors, the pass-gate transistor PG-1 is defined at an intersection o the gate structure 308 and the active structure 306; the first pull-down transistor PD-1 is defined at an intersection of the gate structure 310 and the active structure 306; the second pull-down transistor is defined at an intersection of the gate structure 312 and the active structure 306; and the pass-gate transistor PG-2 is defined at an intersection of the gate structure 314 and the active structure 306. On the other hand, among the P-type transistors, the first pull-up transistor PU-1 is defined at an intersection of the gate structure 310 and the active structure 304, while the second pull-up transistor PU-2 is defined at an intersection of the gate structure 312 and the active structure 304.

Based on such configurations, the P-type well/region and the overlying N-type transistors are arranged at a single side of the N-type well/region and the overlying P-type transistors. As compared to certain configuration that N-type transistors are distributed at both sides of the P-type transistors, the transistor arrangement described according to embodiments of the present disclosure show reduced mismatch among the N-type transistors. Specifically, if the N-type transistors are distributed at both sides of the P-type transistors, the N-type transistors at one side of the P-type transistors and the N-type transistors at the other side of the P-type transistors might have different spacing to the P-type transistors, as a result of inaccuracy during photolithography process. Such mismatch among the N-type transistors may in turn compromise performance of the SRAM cell. Therefore, by arranging the N-type transistors at a single side of the P-type transistors, more reliable performance of the SRAM cell can be ensured.

Moreover, based on such arrangement of the active structures 304, 306 and the gate structures 308, 310, 312, 314, each cell 10 is longer in the column direction Y, while being shorter in the row direction X. In some embodiments, a dimension Dy of each cell 10 along the column direction Y is about 1.2 times to about 2.5 times of a dimension Dx of each cell 10 along the row direction X, and the dimension Dy is substantially equal to 4 times of gate pitch (i.e., pitch of the gate structures 308, 310, 312, 314).

Referring to the plan view 300 illustrating wafer frontside, in each cell 10 (e.g., the cell 10-1), the common source/drain terminal of the pass-gate transistor PG-1 and the first pull-down transistor PD-1 is connected to a source/drain terminal of the first pull-up transistor PU-1, through a lateral contact 316. Further, the lateral contact 316 is connected to the gate structure 312 providing gate terminals for the second pull up transistor PU-2 and the second pull-down transistor PD-2 by a via V0-1 sitting on the lateral contact 316, a conductive line M1-1 extending over the via V0-1 and a gate via VG-1 in contact with the conductive line M1-1 and the gate structure 312 by opposite ends. These connected elements are collectively functioned as the storage node N1 of the cell 10. To implement such connections, the lateral contact 316 may extend along the row direction X, in between the gate structures 308, 310. In addition, the conductive line M1-1 may extend along the column direction Y, across the lateral contact 316 and the gate structures 310, 312.

In a similar way, the common source/drain terminal of the pass-gate transistor PG-2 and the second pull-down transistor PD-2 is connected to a source/drain terminal of the second pull-up transistor PU-2, through a lateral contact 318 at wafer frontside. Further, the lateral contact 318 is connected to the gate structure 310 providing gate terminals for the first pull up transistor PU-1 and the first pull-down transistor PD-1 by a via V0-2 sitting on the lateral contact 318, a conductive line M1-2 extending over the via V0-2 and a gate via VG-2 in contact with the conductive line M1-2 and the gate structure 310 by opposite ends. These connected elements are collectively functioned as the storage node N2 of the cell 10. To implement such connections, the lateral contact 318 may extend along the row direction X, in between the gate structures 312, 314. In addition, the conductive line M1-2 may extend along the column direction Y, and cross over the lateral contact 318 and the gate structures 310, 312. In some embodiments, the conductive lines M1-1, M1-2 are placed next to each other, with the conductive line M1-1 overlapping the active structure 304 and the conductive line M1-2 positioned between the active structures 304, 306.

As one of the source/drain terminals of the pass-gate transistor PG-1 is part of the storage node N1, the other source/drain terminal of the pass-gate transistor PG-1 is connected to the bit line BL, which is at the same height level as the conductive lines M1-1, M1-2 at wafer frontside. A lateral contact 320 and a via V0-3 may be disposed between such source/drain terminal of the pass-gate transistor PG-1 and the bit line BL, to establish connection in between. Specifically, the bit line BL may extend along the column direction Y, and may overlap the active structure 306. While the bit line BL extends along an interface shared by the cells 10-1, 10-2, the lateral contact 320 extending along the row direction X crosses the interface between the cells 10-1, 10-2, to reach into the cell 10-2. Despite that routing the pass-gate transistor PG-1 in the cell 10-1 to the cell 10-2 is not required for the cell 10-1, the lateral contact 320 is designed in such way for connecting the pass-gate transistor PG-1 in the cell 10-2 to the bit line BL running across the cell 10-1. In this way, the bit line BL running across the cell 10-1 can be shared with the cell 10-2. Specifically, one of the source/drain terminals of the pass-gate transistor PG-1 in the cell 10-2 is connected to the bit line BL extending in the cell 10-1 through the lateral contact 320 that reaches into the cell 10-1 from the cell 10-2. To connect the lateral contact 320 to the bit line BL, the via V0-3 is in contact with the lateral contact 320 and the bit line BL by opposite ends, and is positioned within the cell 10-1.

On the other hand, the source/drain terminal of the pass-gate transistor PG-2 not shared with the second pull-down transistor PD-2 is connected to the bit line BLB, which is at the same height level as the conductive lines M1-1, M1-2 and the bit line BL at wafer frontside. The bit line BLB extends along the column direction Y in the cell 10-2, instead of the cell 10-1. To establish such connection, a lateral contact 322 and a via V0-4 are disposed between such source/drain terminal of the pass-gate transistor PG-2 and the bit line BLB. Specifically, the lateral contact 322 extending along the row direction X crosses over the interface shared by the cells 10-1, 10-2, to reach into the cell 10-2, for compensating lateral offset between this source/drain terminal of the pass-gate transistor PG-2 in the cell 10-1 and the bit line BLB running across the cell 10-2. Further, the lateral contact 322 and the via V0-4 are also functioned for connecting one of the source/drain terminals of the pass-gate transistor PG-2 in the cell 10-2 to the bit line BLB. In this way, the bit line BLB running in the cell 10-2 are shared by the cells 10-1, 10-2. In some embodiments, the lateral contacts 320, 322 are designed in the same way, as both extend across the interface between the cells 10-1, 10-2 and overlapped with the bit line BL as well as the bit line BLB. In addition, the via V0-4 is in contact with the lateral contact 322 and the bit line BLB by opposite ends, and positioned within the cell 10-2.

According to the bit line sharing scheme described above, the bit line BL extending in the cell 10-1 is shared by both the cell 10-1 and the cell 10-2. Similarly, the bit line BLB extending in the cell 10-2 is shared by both the cell 10-1 and the cell 10-2 as well. The lateral contacts 320, 322 and the vias V0-3, V0-4 are used for implementing the share scheme.

In addition to be linked with other transistors, the pull-up transistors PU-1, PU-2 in each cell 10 are respectively coupled to the power supply voltage Vdd by a common source/drain terminal, and the pull-down transistors PD-1, PD-2 are each coupled to the reference voltage Vss by a common source/drain terminal. As will be described, the common source/drain terminals of the pull-up transistors PU-1, PU-2 and the pull-down transistors PD-1, PD-2 are connected to the power supply voltage Vdd and the reference voltage Vss via backside power rails.

To ensure successful connection to the voltage sources and to reduce resistance along voltage transmission paths, the common source/drain terminal of the pull-up transistors PU-1, PU-2 in each cell 10 is connected to the common source/drain terminal of the pull-up transistors PU-1, PU-2 in an adjacent cell 10 by a lateral contact 324 at wafer frontside, which is only depicted in half in FIG. 3A. Based on such configuration, even when the pull-up transistors PU-1, PU-2 in one cell 10 fails to be connected to corresponding backside power rail, such pull-up transistors PU-1, PU-2 can still be routed to the backside power rail connected to the pull-up transistors PU-1, PU-2 in an adjacent cell 10 through the lateral contact 324 at wafer frontside. Further, by adding a conduction path in parallel to the power supply voltage Vdd, an equivalent resistance of the conduction paths for transmitting the power supply voltage Vdd can be lowered, so as that voltage drop along the conductive paths can be effectively reduced.

Similarly, the common source/drain terminal of the pull-down transistors PD-1, PD-2 in each cell 10 is connected to the common source/drain terminal of the pull-down transistors PD-1, PD-2 in an adjacent cell 10 by a lateral contact 326 at wafer frontside, which is entirely depicted in FIG. 3A. The lateral contacts 324, 326 may extend along the row direction X, and may be positioned between the gate structures 310, 312. Further, the lateral contacts 324, 326 may be at the same height level as the lateral contacts 316, 318, 320, 322, which lies below the height level of the conductive lines M1-1, M1-2 and the bit lines BL, BLB.

Furthermore, the gate structures 308, 314 providing the gate terminals for the pass-gate transistors PG-1, PG-2 in each cell 10 are connected to one of the word lines WL running over at wafer frontside. To implement such connection, a word line landing pattern M1-3 and gate vias VG-3, VG-4 are disposed. The word line landing pattern M1-3 is at the same height level with the conductive lines M1-1, M1-2 and the bit lines BL, BLB at wafer frontside, and extends along the column direction Y to cross over the gate structures 308, 314. The gate via VG-3 is in contact with the gate structure 308 and the word line landing pattern M1-3 by opposite ends, whereas the gate via VG-4 is in contact with the gate structure 314 and the word line landing pattern M1-3 by opposite ends.

The cells 10-1, 10-2 are in mirror symmetry with respect to the shared interface, in terms of arrangement of the active structures 304, 306 and the gate structures 308, 310, 312, 314. In addition, the lateral contacts 316, 318 in the cell 10-1 may be placed with mirror symmetry to the lateral contacts 316, 318, 324 in the cell 10-2, with respect to the interface shared by the cells 10-1, 10-2. Further, as described, the cells 10-1, 10-2 share the lateral contacts 320, 322, 326 extending across the shared interface. Although not shown, the cells 10-1 and another adjacent cell 10 may share the lateral contact 324 extending across the interface in between. In the same way, the cell 10-2 and another adjacent cell 10 may share the lateral contact 324 extending across the interface in between.

Nonetheless, the cells 10-1, 10-2 may be different from each other in terms of trace and via arrangement at wafer frontside. Specifically, in some embodiments, the word line landing pattern M1-3, the conductive line M1-1, the conductive line M1-2 and the bit line BL in the cell 10-1 are arranged in order toward the interface shared by the cells 10-1, 10-2. In these embodiments, on the other hand, the word line landing pattern M1-3, the conductive line M1-2, the bit line BLB and the conductive line M1-1 in the cell 10-2 are arranged in order toward the interface shared by the cells 10-1, 10-2. In this way, the shared bit lines BL, BLB can be spaced apart with the conductive line M1-1 of the cell 10-2 in between, and thus can be properly isolated from each other. As the trace arrangement of the cell 10-2 is different from the trace arrangement of the cell 10-1, via arrangement in the cell 10-2 must adapt accordingly.

As described, the common source/drain terminal of the pull-up transistors PU-1, PU-2 and the common source/drain terminal of the pull-down transistors PD-1, PD-2 in each cell 10 are connected to backside power rails. Referring to the plan view 302 illustrating wafer backside, in each cell 10, the common source/drain terminal of the pull-up transistors PU-1, PU-2 is in contact with a backside contact 328 by its backside, and is connected to a backside power rail BM1-1 through the backside contact 328. Similarly, in each cell 10, the common source/drain terminal of the pull-down transistors PD-1, PD-2 is in contact with a backside contact 330 by its backside, and is connected to a backside power rail BM1-2 through the backside contact 330. The backside contact 328 is overlapped with the lateral contact 324 at wafer frontside, since they are in contact with the same source/drain terminal from opposite sides. Similarly, the backside contact 330 is overlapped with the lateral contacts 326 at wafer frontside, as they are in contact with the same source/drain terminal from opposite sides. In addition, the backside power rails BM1-1, BM1-2 at wafer backside are formed over the backside contacts 328, 330, with the backside power rail BM1-1 coupled to the power supply voltage Vdd and the backside power rail BM1-2 coupled to the reference voltage Vss. According to some embodiments, in each cell 10, the backside power rails BM1-1, BM1-2 at the same height level extend along the column direction Y, and may overlap the active structures 304, 306, respectively. Further, the cells 10-1, 10-2 may be in mirror symmetry with respect the shared interface, in terms of arrangement of the backside contacts 328, 330 and the backside power rails BM1-1, BM1-2.

The common source/drain terminal of the pull-up transistors PU-1, PU-2 in each cell 10 i connected to a respective one of the backside power rail BM1-1 through the backside contact 328 in between. As described, the lateral contacts 324 at wafer frontside are respectively configured to bridge the common source/drain terminal of the pull-up transistors PU-1, PU-2 in one cell 10 to the common source/drain terminal of the pull-up transistors PU-1, PU-2 in an adjacent cell 10. In this way, even when the pull-up transistors PU-1, PU-2 in one cell 10 fail to be connected to the corresponding backside power rail BM1-1 by the backside contact 328 in between, such pull-up transistors PU-1, PU-2 can still be routed to the backside power rail BM1-1 connected to the pull-up transistors PU-1, PU-2 in an adjacent cell 10 through the corresponding lateral contact 324. Therefore, powering of the pull-up transistors PU-1, PU-2 can be ensured, even when some of the backside contacts 328 fail to be correctly positioned on the corresponding source/drain terminals. Further, as the lateral contacts 324 can be functioned as additional conduction paths in parallel to the power supply voltage Vdd, an equivalent resistance of the conduction paths for transmitting the power supply voltage Vdd can be lowered, so as that voltage drop along the conductive paths can be effectively reduced.

Similarly, the common source/drain terminal of the pull-down transistors PD-1, PD-2 in each cell 10 is connected to a respective one of the backside power rail BM1-2 through the backside contact 330 in between. As described, the lateral contacts 326 at wafer frontside are respectively configured to bridge the common source/drain terminal of the pull-down transistors PD-1, PD-2 in one cell 10 to the common source/drain terminal of the pull-down transistors PD-1, PD-2 in an adjacent cell 10. In this way, even when the pull-down transistors PD-1, PD-2 in one cell 10 fail to be connected to the corresponding backside power rail BM1-2 by the backside contact 330 in between, such pull-down transistors PD-1, PD-2 can still be routed to the backside power rail BM1-2 connected to the pull-down transistors PD-1, PD-2 in an adjacent cell 10 through the corresponding lateral contact 326. Therefore, deliver of the reference voltage Vss to the pull-down transistors PD-1, PD-2 can be ensured, even when some of the backside contacts 330 fail to be correctly positioned on the corresponding source/drain terminals. Further, as the lateral contacts 326 can be functioned as additional conduction paths in parallel to the reference voltage Vss, an equivalent resistance of the conduction paths for transmitting the reference voltage Vss can be lowered, so as that voltage drop along the conductive paths can be effectively reduced.

When each cell 10 is designed to be longer in the column direction Y but shorter in the row direction X (i.e., the dimension Dy is greater than the dimension Dx), the bit line sharing scheme can ensure that the bit lines BL, BLB extending along the column direction Y can be formed with sufficiently large line width at the same metallization tier as the conductive lines M1-1, M1-2 and the word line landing patterns M1-3. Specifically, if each cell 10 is connected to two bit lines passing through, the bit lines and the conductive lines M1-1, M1-2 as well as the word line landing pattern M1-3 have to be formed within the dimension Dx, thus line with and spacing to other traces for the bit lines are certainly limited. Alternatively, the bit lines have to be moved to higher metallization tier, and parasitic capacitance along bit line connection paths can be adversely increased. By adopting the bit line sharing scheme, only one bit line BL/BLB passes through each cell 10, thus more space in the metallization tier containing the conductive lines M1-1, M1-2 and the word line landing patterns M1-3 can be used for the bit lines BL, BLB. Therefore, the bit lines BL, BLB can be formed with sufficient line width at the same height level as the conductive lines M1-1, M1-2 and the word line landing patterns M1-3, instead of being moved to higher metallization tier. Accordingly, resistance along the bit lines BL, BLB can be reduced, and parasitic capacitance along bit line connection paths can be lowered as well. According to some embodiments, the line width of the bit lines BL, BLB is about 1.5 times to about 5 times of a line width of each of the conductive lines M1-1, M1-2 and the word line landing patterns M1-3 at the same metallization tier with the bit lines BL, BLB.

FIG. 3B includes schematic plan views 300a, 302a showing metallization tiers next to the ones shown by the plan views 300, 302 in FIG. 3A, according to some embodiments of the present disclosure.

Specifically, the plan view 300a schematically illustrates a metallization tier above a metallization tier including the conductive lines M1-1, M1-2, the bit lines BL, BLB and the word line landing patterns M1-3 at wafer frontside. The conductive lines M1-1, M1-2, the bit lines BL, BLB and the word line landing patterns M1-3 at the lower metallization tier are also shown in the plan view 300a, for specifying relationship between these upper and lower metallization tiers at wafer frontside.

According to some embodiments, the word lines WL are deployed at the metallization tier next to the metallization tier containing the conductive lines M1-1, M1-2, the bit lines BL, BLB and the word line landing patterns M1-3. As the conductive lines M1-1, M1-2, the bit lines BL, BLB and the word line landing patterns M1-3 extend along the column direction Y, the word lines WL may extend along the row direction X. The cells 10 in each row may be alternately connected to a pair of the word lines WL. As an example, the cell 10-1 is connected to the word line WL-1 from the word line landing pattern M1-3 passing through, whereas the cell 10-2 is connected to the word line WL-2 form the word line landing pattern M1-3 passing through. Although not shown, following this rule, other cells 10 placed at right side of the cell 10-2 along a row are alternately connected to the word lines WL-1, WL-2.

As described, by adopting the bit line sharing scheme, the bit lines BL, BLB can be formed at the same metallization tier as the conductive lines M1-1, M1-2 and the word line landing patterns M1-3, rather than being moved to a higher metallization tier, such as the metallization tier formed with the word lines WL. Therefore, without sharing the same metallization tier with the bit lines BL, BLB, the word lines WL can be formed with sufficient line width, thus resistance along the word lines WL can be reduced.

Vias disposed between the word lines WL and the word line landing patterns M1-3 are used for establishing connection in between. For instance, the word line landing pattern M1-3 passing through the cell 10-1 is connected to the word line WL-1 through a via V1-1, which is in contact with the word line landing pattern M1-3 and the word line WL-1 by opposite ends. In addition, the word line landing pattern M1-3 passing through the cell 10-2 is connected to the word line WL-2 through a via V1-2, which is in contact with the word line landing pattern M1-3 and the word line WL-2 by opposite ends.

On the other hand, the plan view 302a schematically illustrates a backside metallization tier over a backside metallization tier including the backside power rails BM1-1, BM1-2. The backside power rails BM1-1, BM1-2 at lower backside metallization tier are also shown in the plan view 302a, for specifying relationship between these upper and lower metallization tiers at wafer backside.

According to some embodiments, at least one backside power rail BM2 is formed over the backside power rails BM1-1, BM1-2 at wafer backside, for routing the backside power rails BM1-2 to the reference voltage Vss provided from backside of the entire chip/wafer structure. As the backside power rails BM1-1, BM1-2 extend along the column direction Y, the backside power rail BM2 may extend along the row direction X, and intersect the backside power rails BM1-1, BM1-2. In some embodiments, each backside power rail BM2 is connected to some or all of the intersecting backside power rails BM1-2. For instance, the backside power rail BM2 shown in FIG. 3B is connected to each of the backside power rails BM1-2 passing through the cells 10-1, 10-2, and backside vias BV-1, BV-2 are used for establishing connection therebetween. In this way, the lateral contacts 326 are connected in parallel with the backside power rail BM2, and an equivalent resistance along the conduction paths for transmitting the reference voltage Vss can be reduced.

Although not shown, more backside metallization tiers may further stack on the backside metallization tier containing the backside power rail BM2, for routing the backside power rails BM1-1 to the power supply voltage Vdd, and for routing the backside power rails BM1-2, BM2 to the reference voltage Vss. As similar to the lateral contacts 326 and the backside power rails BM2, the lateral contacts 324 may be connected in parallel with some backside power rails coupled to the power supply voltage Vdd, so as to reduce resistance along the conduction paths for transmitting the power supply voltage Vdd. These backside contacts, traces and vias collectively form backside power distribution network.

As the transistors in the SRAM cells 10 are powered from wafer backside, wafer frontside may not be formed with power distribution network. Since the power distribution network is disposed at less crowded wafer backside (as compared to wafer frontside), the power distribution network can be formed with backside power rails (i.e., the backside power rails BM1-1, BM1-2, BM2 and the like) having greater line width, and resistance along the paths can be significant reduced. Also, routing area at wafer frontside can be released, such that the word lines WL and the bit lines BL, BLB at wafer frontside can be formed with greater line width and sufficient spacing to other frontside traces.

Several variations can be made to the layout design described with reference to FIG. 3A and FIG. 3B, to further improve SRAM performance.

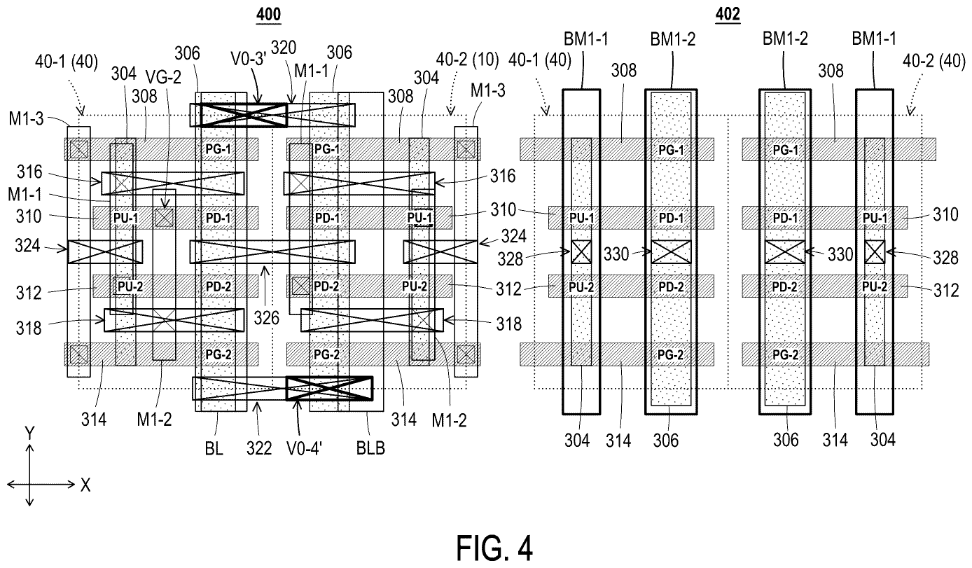

FIG. 4 includes schematic plan views 400, 402 showing layout design of adjacent SRAM cells 40 at wafer frontside and wafer backside, according to some embodiments of the present disclosure.

Specifically, the plan view 400 schematically illustrates layout patterns of adjacent cells 40-1, 40-2 at wafer frontside, according to these embodiments. Meanwhile, the plan view 402 schematically illustrates layout patterns of the adjacent cells 40-1, 40-2 at wafer backside, according to these embodiments.

In terms of layout design at wafer backside, the cells 40 are substantially identical with the cells 10 described above. That is, the layout patterns at first backside metallization tier as shown in the plan view 402 are substantially identical with the layout patterns at the first backside metallization tier as shown in the plan view 302 of FIG. 3A. Although not shown, the cells 40 may further include further backside metallization tiers stacked on the first backside metallization tier, as described with reference to the plan view 302a of FIG. 3B.

On the other hand, the cells 40 is different from the cells 10 in layout design at wafer frontside, and more particularly, in the vias configured to connect the lateral contacts 320, 322 to the bit lines BL, BLB. As shown in the plan view 300 of FIG. 3A, the via V0-3 connecting the lateral contact 320 to the bit line BL is entirely overlapped by the bit line BL, and is smaller in width as compared to the bit line BL. Similarly, the via V0-4 connecting the lateral contact 322 to the bit line BLB is entirely overlapped by the bit line BLB, and is smaller in width as compared to the bit line BLB. In contrast, the lateral contact 320 shared by the cells 40-1, 40-2 as shown in FIG. 4 is connected to the bit line BL by a via V0-3′ further extending from span of the bit line BL. Similarly, the lateral contact 322 shared by the cells 40-1, 40-2 is connected to the bit line BLB by a via V0-4′ further extending from span of the bit line BLB.

Specifically, the long via V0-3′ extends from one lateral side of the bit line BL to the other lateral side of the bit line BL, and further extends along the underlying lateral contact 320, to be laterally protruded with respect to the bit line BL. In this way, a portion of the long via V0-3′ is overlapped with the bit line BL, whereas another portion of the long via V0-3′ is not covered by the bit line BL. According to some embodiments, the long via V0-3′ crosses over the interface shared by the cells 40-1, 40-2 to reach into the cell 40-2, but must be spaced apart from the bit line BLB passing through the cell 40-2. As an example, a length of the via V0-3′ defined as a dimension along the row direction X is about 2 to about 5 times of a width of the via V 0-3′ defined as a dimension along the column direction Y. By using the long via V0-3′ providing additional conduction path along the row direction X, the pass-gate transistor PG-1 in the cell 40-2 can be connected to the bit line BL passing through the cell 40-1, with a lower resistance along the way.

Similarly, the long via V0-4′ extends from below the bit line BLB, to be laterally protruded with respect to the bit line BLB. As shown in FIG. 4, the long via V0-4′ does not span across the entire width of the bit line BLB. However, in alternative embodiments, the long via V0-4′ extends from one lateral side of the bit line BLB to the other lateral side of the bit line BLB, and beyond. In either cases, the long via V0-4′ extends along the lateral contact 322, and a portion of the long via V0-4′ is overlapped with the bit line BLB, while another portion of the long via V0-4′ is not covered by the bit line BLB. According to some embodiments, as the bit line BLB is more distant from the interface shared by the cells 40-1, 40-2 as compared to the bit line BL, and the long via V0-4′ extending from the bit line BLB does not cross over the interface shared by the cells 40-1, 40-2. In alternative embodiments, the long via V0-4′ does reach the interface, or even cross over the interface to reach into the cell 40-1. However, in either way, the long via V0-4′ would be kept separated from the bit line BL. As an example, a length of the via V0-4′ defined as a dimension along the row direction X is about 2 to about 5 times of a width of the via V 0-4′ defined as a dimension along the column direction Y. By using the long via V0-4′ providing additional conduction path along the row direction X, the pass-gate transistor PG-2 in the cell 40-1 can be connected to the bit line BLB passing through the cell 40-2, with a lower resistance along the way.

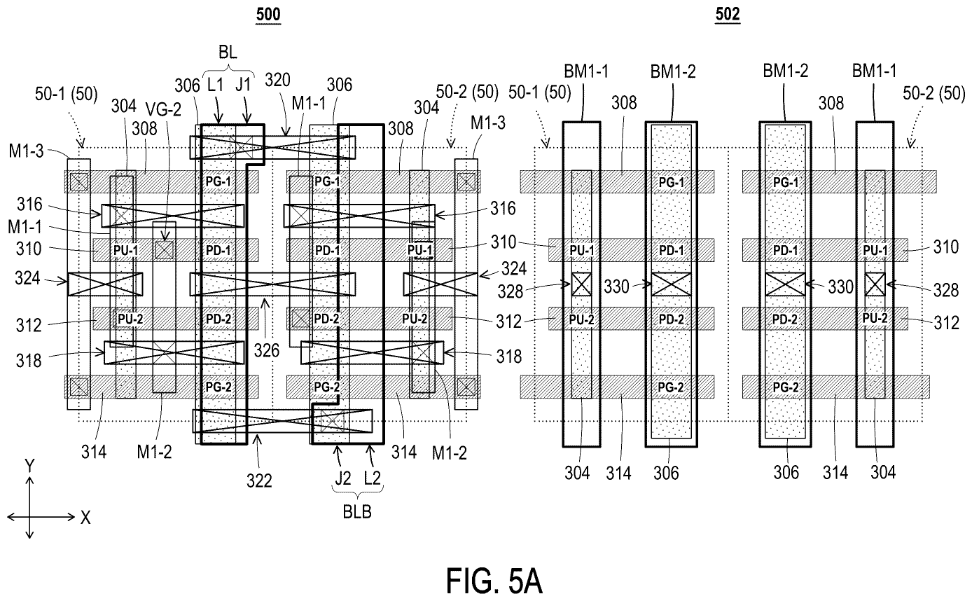

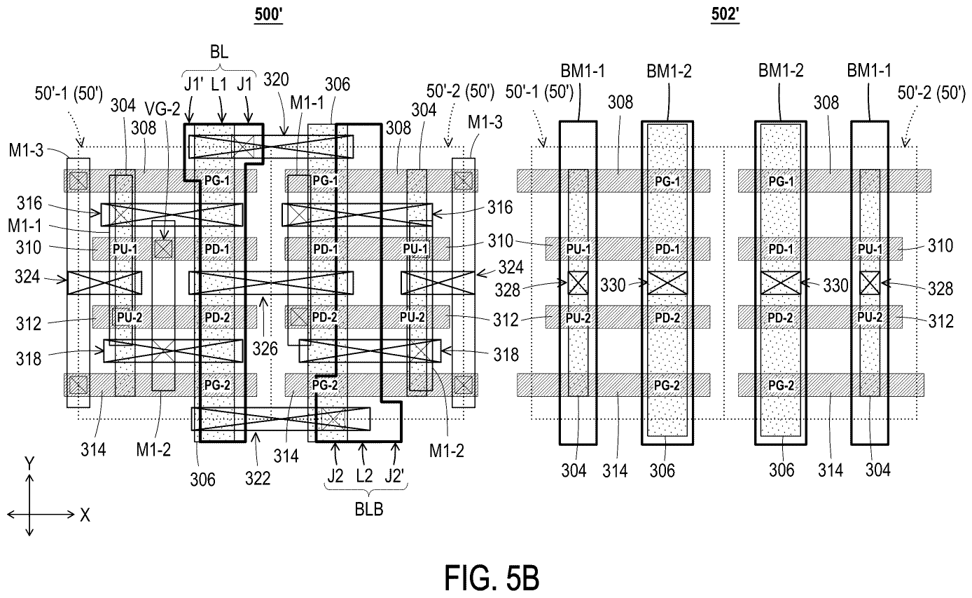

FIG. 5A includes schematic plan views 500, 502 showing layout design of adjacent SRAM cells 50 at wafer frontside and wafer backside, according to some embodiments of the present disclosure.

Specifically, the plan view 500 schematically illustrates layout patterns of adjacent cells 50-1, 50-2 at wafer frontside, according to these embodiments. Meanwhile, the plan view 502 schematically illustrates layout patterns of the adjacent cells 50-1, 50-2 at wafer backside, according to these embodiments.

In terms of layout design at wafer backside, the cells 50 are substantially identical with the cells 10, 40 described above. That is, the layout patterns at first backside metallization tier as shown in the plan view 502 are substantially identical with the layout patterns at the first backside metallization tier as shown in the plan view 302 of FIG. 3A. Although not shown, the cells 50 may further include further backside metallization tiers stacked on the first backside metallization tier, as described with reference to the plan view 302a of FIG. 3B.

On the other hand, the cells 50 are different from the cells 10 in layout design at wafer frontside, and more particularly, in pattern design of the bit lines BL, BLB. As shown in the plan view 500, the bit line BL is locally widened, and laterally protrudes toward the bit line BLB along the lateral contact 320, to form a jog portion J1 aside a main linear portion L1 of the bit line BL and lying over the lateral contact 320. Based on such design, the via V0-3 configured to connect the lateral contact 320 to the bit line BL can be shifted toward the bit line BLB, and overlapped with the jog portion J1 of the bit line BL. As the via V0-3 is closer to the cell 50-2 through which the bit line BLB passes, the pass-gate transistor PG-1 in the cell 50-2 can be connected to the bit line BL passing through the cell 50-1 by a shorter conduction path, thus resistance along the path therebetween can be lowered. According to some embodiments, the jog portion J1 of the bit line BL does not reach the interface shared by the cells 50-1, 502.

Similarly, the bit line BLB is locally widened, and laterally protrudes toward the bit line BL along the lateral contact 322, to form a jog portion J2 aside a main linear portion L2 of the bit line BLB and lying over the lateral contact 322. Based on such design, the via V0-4 configured to connect the lateral contact 322 to the bit line BLB can be shifted toward the bit line BL, and overlapped with the jog portion J2 of the bit line BLB. As the via V0-4 is closer to the cell 50-1 through which the bit line BL passes, the pass-gate transistor PG-2 in the cell 50-1 can be connected to the bit line BLB passing through the cell 50-2 by a shorter conduction path, thus resistance along the path therebetween can be lowered. According to some embodiments, the jog portion J2 of the bit line BLB does not reach the interface shared by the cells 50-1, 502.

FIG. 5B includes schematic plan views 500′, 502′ showing layout design of adjacent SRAM cells 50′ at wafer frontside and wafer backside, according to some embodiments of the present disclosure.

Specifically, the plan view 500′ schematically illustrates layout patterns of adjacent cells 50′-1, 50′-2 at wafer frontside, according to these embodiments. Meanwhile, the plan view 502′ schematically illustrates layout patterns of the adjacent cells 50′-1, 50′-2 at wafer backside, according to these embodiments.

In terms of layout design at wafer backside, the cells 50′ are substantially identical with the cells 10, 40, 50 described above. That is, the layout patterns at first backside metallization tier as shown in the plan view 502′ are substantially identical with the layout patterns at the first backside metallization tier as shown in the plan view 302 of FIG. 3A. Although not shown, the cells 50′ may further include further backside metallization tiers stacked on the first backside metallization tier, as described with reference to the plan view 302a of FIG. 3B.

In addition, layout design of the cells 50′ at wafer frontside are very similar to the layout design of the cells 50 at wafer frontside, except for a few differences. As shown by the plan view 500 of FIG. 5A, the bit line BL has local protrusion at single side, which is the side facing toward the bit line BLB. Similarly, the bit line BLB has local protrusion only at the side facing toward the bit line BL. In contrast, as shown by the plan view 500′ in FIG. 5B, the bit lines BL, BLB both locally protrude from two opposite lateral sides.

Specifically, in addition to having the jog portion J1 protruding toward the bit line BLB with respect to the linear portion L1, the bit line BL further has another jog portion J1′ laterally protruding from the other lateral side of the linear portion L1. The jog portions J1, J1′ may both overlap the lateral contact 320, but are located at opposite sides of the linear portion L1. The jog portion J1 is rather close to the nearest trace (which is the conductive line M1-1 in the cell 50′-2) in the column direction. Meanwhile, the jog portion J1′ is rather distant from the nearest trace (which is the conductive line M1-2 in the cell 50′-1) in the column direction Y. Considering optical proximity effect, the jog portion J1 may be shorter in terms of its dimension along the column direction Y, as compared to the jog portion J1′. In addition, considering the jog portion J1 has to entirely overlap the via V0-3, the jog portion J1 may be greater in its dimension along the row direction X, as compared to the jog portion J1′. Alternatively, the jog portions J1, J1′ may have substantially the same dimension along the row direction X. By having both the jog portion J1 and the jog portion J1′, resistance along the bit line BL can be further reduced.

Similarly, in addition to having the jog portion J2 protruding toward the bit line BL with respect to the linear portion L2, the bit line BLB further has another jog portion J2′ laterally protruding from the other lateral side of the linear portion L2. The jog portions J2, J2′ may both be positioned along an extending direction of the lateral contact 322, but are located at opposite sides of the linear portion L2. The jog portion J2′ is rather close to the nearest trace (which is the conductive line M1-2 in the cell 50′-2) in the column direction. Meanwhile, the jog portion J2 is rather distant from the nearest trace (which is the conductive line M1-1 in the cell 50′-2) in the column direction Y. Considering optical proximity effect, the jog portion J2′ may be shorter in terms of its dimension along the column direction Y, as compared to the jog portion J2. In addition, considering the jog portion J2 has to entirely overlap the via V0-4, the jog portion J2 may be greater in its dimension along the row direction X, as compared to the jog portion J2′. Alternatively, the jog portions J2, J2′ may have substantially the same dimension along the row direction X. By having both the jog portion J2 and the jog portion J2′, resistance along the bit line BLB can be further reduced.

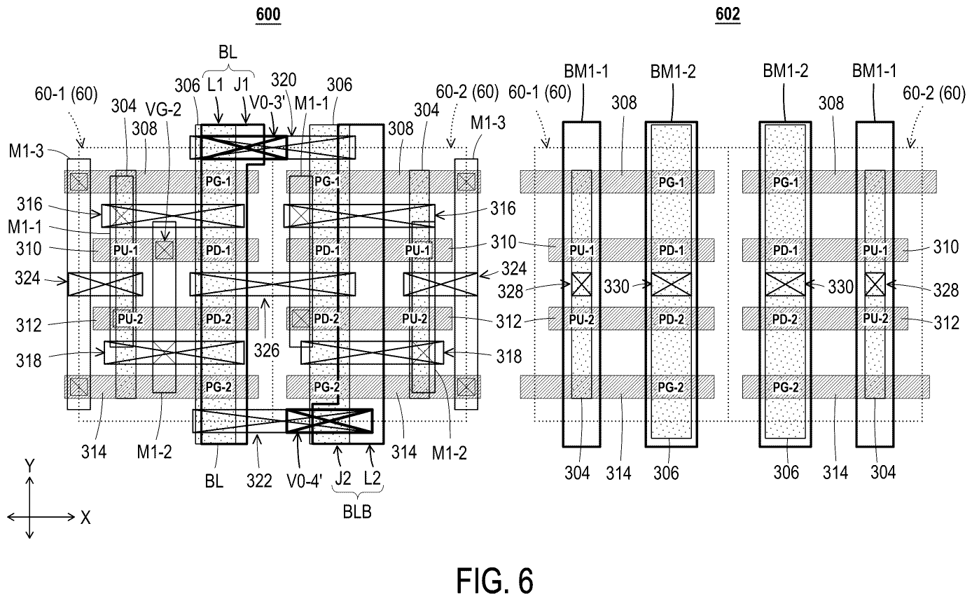

FIG. 6 includes schematic plan views 600, 602 showing layout design of adjacent SRAM cells 60 at wafer frontside and wafer backside, according to some embodiments of the present disclosure.

Specifically, the plan view 600 schematically illustrates layout patterns of adjacent cells 60-1, 60-2 at wafer frontside, according to these embodiments. Meanwhile, the plan view 602 schematically illustrates layout patterns of the adjacent cells 60-1, 60-2 at wafer backside, according to these embodiments.

In terms of layout design at wafer backside, the cells 60 are substantially identical with the cells 10, 40, 50, 50′ described above. That is, the layout patterns at first backside metallization tier as shown in the plan view 602 are substantially identical with the layout patterns at the first backside metallization tier as shown in the plan view 302 of FIG. 3A. Although not shown, the cells 60 may further include further backside metallization tiers stacked on the first backside metallization tier, as described with reference to the plan view 302a of FIG. 3B.

On the other hand, layout design of the cells 60 at wafer frontside is a result of modifying the layout design of the cells 10 described with reference to FIG. 3A and FIG. 3B, by using the long vias V0-3′, V0-4′ as shown in FIG. 4 and the pattern design of the bit lines BL, BLB shown in FIG. 5A. By adopting the combination of the long vias V0-3′, V0-4′ and the jog design of the bit lines BL, BLB, resistance along the conduction paths for implementing bit line sharing scheme can be further reduced.

Although not shown, the layout design of the cells 10 described with reference to FIG. 3A and FIG. 3B can be further modified by using the long vias V0-3′, V0-4′ as shown in FIG. 4 and the pattern design of the bit lines BL, BLB as shown in FIG. 5B, such that the bit lines BL, BLB with double jog portions are coupled to the long vias V0-3′, V0-4′.

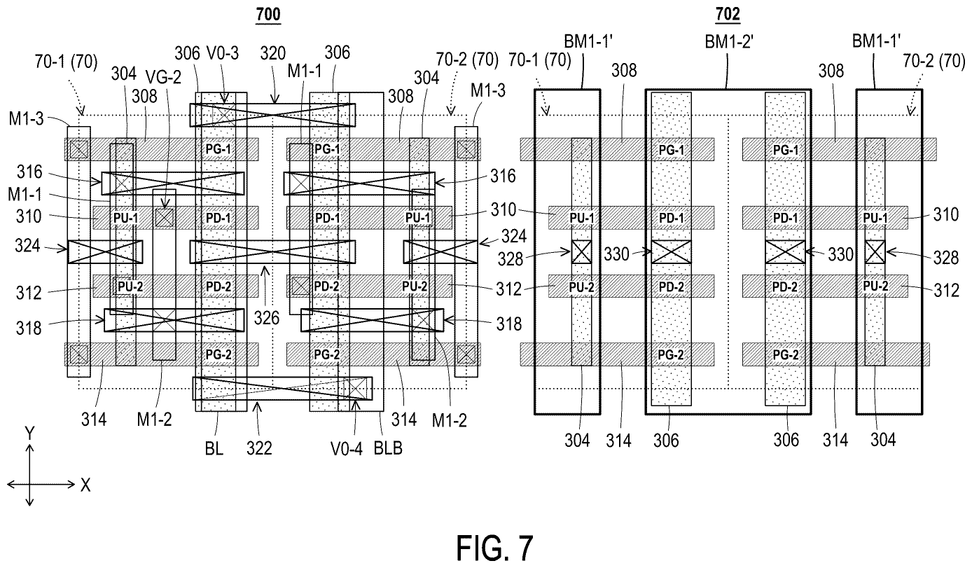

FIG. 7 includes schematic plan views 700, 702 showing layout design of adjacent SRAM cells 70 at wafer frontside and wafer backside, according to some embodiments of the present disclosure.

Specifically, the plan view 700 schematically illustrates layout patterns of adjacent cells 70-1, 70-2 at wafer frontside, according to these embodiments. Meanwhile, the plan view 702 schematically illustrates layout patterns of the adjacent cells 70-1, 70-2 at wafer backside, according to these embodiments.

In terms of layout design at wafer frontside, the cells 70 are substantially identical with the cells 10 described above. That is, the layout patterns from the active structures, the gate structures to the first frontside metallization tier as shown in the plan view 702 are substantially identical with the layout patterns from the active structures, the gate structures to the first metallization tier as shown in the plan view 300 of FIG. 3A. Although not shown, the cells 70 may further include further frontside metallization tiers stacked on the first frontside metallization tier, as described with reference to the plan view 300 of FIG. 3B.

On the other hand, the cells 70 are different from the cells 10 in layout design at wafer backside, and more particularly, in pattern design of the backside power rails at the first backside metallization tier. As shown by the plan view 302 in FIG. 3A, the pull-up transistors PU-1, PU-2 and the pull-down transistors PD-1, PD-2 in each cell 10 are powered by a dedicated pair of the backside power rails BM1-1, BM1-2, and adjacent cells 10 do not share any of the backside power rails BM1-1, BM1-2. In contrast, as shown by the plan view 702 in FIG. 7, the pull-down transistors PD-1, PD-2 in the cell 70-1 and the pull-down transistors PD-1, PD-2 in the cell 70-2 are powered by a single backside power rail BM1-2′. The backside power rail BM1-2′ spans across the interface between the cells 70-1, 70-2, so as to be shared by the cells 70-1, 70-2. Specifically, the backside power rail BM1-2′ laterally spans, to overlap the active structure 306 in the cell 70-1 and the active structure 306 in the cell 70-2. Although not shown, the pull-up transistors PU-1, PU-2 in the cell 70-1 and the pull-up transistors PU-1, PU-2 in another cell 70 next to the cell 70-1 are powered by a single backside power rail BM1-1′ that spans across the interface in between. Similarly, the pull-up transistors PU-1, PU-2 in the cell 70-2 and the pull-up transistors PU-1, PU-2 in another cell 70 next to the cell 70-2 are powered by a single backside power rail BM1-1′ that spans across the interface in between.

Besides design of the first backside metallization tier, design of the backside contacts and the second and higher backside metallization tiers may be the same for the cells 10 and the cells 70. Moreover, although not shown, the variations described with reference to FIG. 4, FIG. 5A, FIG. 5B and FIG. 6 can be applied to the layout design at wafer frontside as shown by the plan view 700 in FIG. 7.

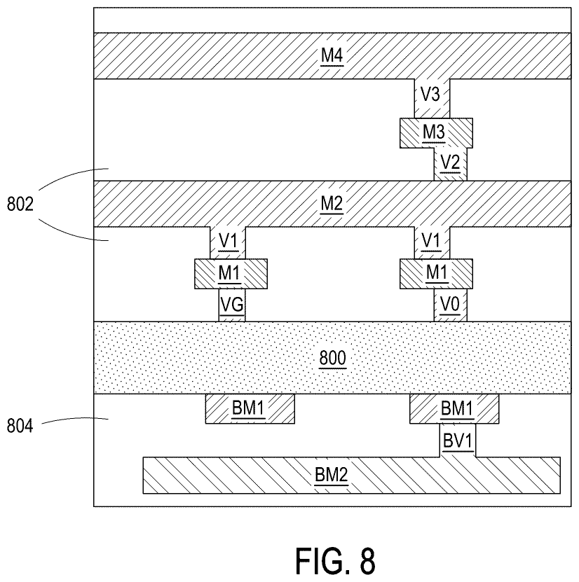

In order to specify configuration of the above-described layout patterns along a vertical direction, FIG. 8 provides a simplified cross-sectional view showing stacking order of representative ones of these layout patterns.

A device layer 800 contains the SRAM transistors defined at the intersections of the active structures 304, 306 and the gate structures 308, 310, 312, 314, along with the frontside contacts 316, 318, 320, 322, 324, 326 as well as the backside contacts 328, 330. Wafer frontside is defined as a top side of the device layer 800 shown in FIG. 8, whereas wafer backside is defined as a bottom side of the device layer 800 shown in FIG. 8.

At wafer frontside, gate vias VG and ground tier vias V0 connect the transistors in the device layer 800 to overlying traces M1 at a first frontside metallization tier. Further, first tier vias V1 connect the traces M1 at the first frontside metallization tier to overlying traces M2 at a second frontside metallization tier. The gate vias VG may include the gate VG-1, VG-2, VG-3, VG-4; the ground tier vias V0 may include the vias V0-1, V0-2, V0-3/V0-3′, V0-4/V0-4′; the traces M1 at the first frontside metallization tier may include the conductive lines M1-1, M1-2, the bit lines BL, BLB and the word line landing patterns M1-3; the first tier vias V1 may include the vias V1-1, V1-2; and the traces M2 at the second frontside metallization tier may include the word lines WL.

In some embodiments, additional frontside metallization tiers are further formed on the traces M2 at the second frontside metallization tier. As an example, second tier vias V2 connect the traces M2 at the second metallization tier to traces M3 at a third frontside metallization tier. Further, third tier vias V3 may connect the traces M3 at the third frontside metallization tier to traces M4 at a fourth frontside metallization tier.

On the other hand, at wafer backside, traces BM1 at a first backside metallization tier provide the backside power rails BM1-1/BM1-1′, BM1-2/BM1-2′ for powering the transistors in the device layer 800. In addition, backside vias BV1 including the backside vias BV-1, BV2 described above connect the traces BM1 at the first backside metallization tier to the backside power rails BM2 at a second backside metallization tier.

The conductive features at wafer frontside are embedded in a stack of interlayer dielectric layers 802. Similarly, the conductive features at wafer backside are embedded in a stack of interlayer dielectric layers 804. Although not shown, electrical connectors as inputs/outputs (I/Os) may be further deployed at bottom side of the interlayer dielectric layers 804 and/or top side of the interlayer dielectric layers 802.

As above, a SRAM with stable performance, bit line sharing scheme and backside power distribution network is provided. In each cell of the SRAM, N-type transistors are all arranged along a column at a single side of P-type transistors, and the N-type transistors can be easily controlled to be equally spaced apart from the P-type transistors. Therefore, mismatch among the N-type transistors can be reduced, and performance stability of the SRAM can be improved. To implement such arrangement, each cell is designed with longer dimension in column direction and shorter dimension in row direction. As bit lines are arranged along the row direction, it would greatly limit width and pitch of the bit lines if each cell is passed through by a pair of the bit lines. If some of the bit lines are moved to higher metallization tier, then resistance and parasitic capacitance for bit line connection would adversely increase. According to embodiments of the present disclosure, each bit line is shared by two adjacent cells arranged along the row direction. Base on this configuration, each cell is only passed through by a single one of the bit lines. Thereby, the bit lines can be all arranged in a low metallization tier, with sufficient width and pitch. Accordingly, word lines do not have to share a metallization tier with some of the bit lines, and can be formed with greater width and pitch as well. Moreover, as the power distribution network is designed at wafer backside, which is much less crowded than wafer frontside, it benefits from lower resistance and parasitic capacitance along the paths of the power distribution network. Also, wafer frontside can have more room for local and global lines. As insurance and measure for further lowering resistance along the paths of the power distribution network, power nodes (i.e., common source/drain terminal of the pull-down transistors and common source/drain terminal of the pull-up transistors in each cell) of adjacent cells are bridged by lateral contacts at wafer frontside. If the power node of one of the cells fails to be directly connected to the power distribution network, it can still be routed to the power distribution network through the corresponding lateral contact and the power node of an adjacent cell. Moreover, such lateral contacts are connected in parallel with the power distribution network, thus enable lower resistance for power transmission.

In an aspect of the present disclosure, an integrated circuit is provided. The integrated circuit comprises: memory cells, respectively comprising an inverter and two pass-gate transistors coupled to two data nodes of the inverter; pairs of bit lines, passing through the memory cells from above the memory cells, and coupled to the data nodes through the pass-gate transistors, wherein each memory cell is intersected with a single one of the bit lines, and connected to the intersected one of the bit lines as well as another one of the bit lines passing through an adjacent one of the memory cells; and a power distribution network, powering the memory cells from below the memory cells.

In another aspect of the present disclosure, an integrated circuit is provided. The integrated circuit comprises: memory cells, respectively comprising: a first active structure and a second active structure, separately extending along a column direction; and a first gate structure, a second gate structure, a third gate structure and a fourth gate structure, separately extending along a row direction and arranged in order along the column direction, to cover and intersect each of the first and second active structures, wherein N-type transistors comprising a first pass-gate transistor, a first pull-down transistor, a second pull-down transistor and a second pass-gate transistor are defined at intersections of the first active structure and the first to fourth gate structures respectively, and P-type transistors comprising a first pull-up transistor and a second pull-up transistor are defined at intersections of the second active structure and the first to fourth gate structures respectively; bit lines, lying over and passing through the memory cells along the column direction, wherein the first pass-gate transistor in a first memory cell of the memory cells is connected to a first bit line of the bit lines which intersects the first memory cell, and the second pass-gate transistor in the first memory cell is connected to a second bit line of the bit lines which intersects a second memory cell of the memory cells that is next to the first memory cell; and a power distribution network, powering the memory cells from below the memory cells.

In yet another aspect of the present disclosure, an integrated circuit is provided. The integrated circuit comprises: a power distribution network, comprising layers of power rails; a first memory cell and a second memory cell next to each other, disposed on the power distribution network, wherein each of the first and second memory cells comprises: a first active structure and a second active structure, respectively extending along and overlapping one of the power rails; and a first gate structure, a second gate structure, a third gate structure and a fourth gate structure, covering and intersecting each of the first and second active structures, wherein N-type transistors comprising a first pass-gate transistor, a first pull-down transistor, a second pull-down transistor and a second pass-gate transistor are defined at intersections of the first active structure and the first to fourth gate structures, P-type transistors comprising a first pull-up transistor and a second pull-up transistor are defined at intersections of the second active structure and the first to fourth gate structures, the first and second pull-down transistors are connected to the power rail overlapped with the first active structure by a common source/drain terminal, and the first and second pull-up transistors are connected to the power rail overlapped with the second active structure by a common source/drain terminal; and bit lines, lying over and crossing the memory cells, wherein the first pass-gate transistor in the first memory cell is connected to a first bit line of the bit lines which intersects the first memory cell, and the second pass-gate transistor in the first memory cell is connected to a second bit line of the bit lines which intersects the second memory cell.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
memory cells, respectively comprising an inverter and two pass-gate transistors coupled to two data nodes of the inverter;
pairs of bit lines, passing through the memory cells from above the memory cells, and coupled to the data nodes through the pass-gate transistors, wherein each memory cell is intersected with a single one of the bit lines, and connected to the intersected one of the bit lines as well as another one of the bit lines passing through an adjacent one of the memory cells; and
a power distribution network, powering the memory cells from below the memory cells.

2. The integrated circuit according to claim 1, wherein the inverter in each memory cell comprises a first pull-up transistor, a first pull-down transistor, a second pull-up transistor and a second pull-down transistor, wherein a common source/drain terminal of the first and second pull-down transistors in each memory cell is bridged to a common source/drain terminal of the first and second pull-down transistors in an adjacent one of the memory cells through a first lateral contact, and a common source/drain terminal of the first and second pull-up transistors in each memory cell is bridged to a common source/drain terminal of the first and second pull-up transistors in an adjacent one of the memory cells through a second lateral contact.

3. The integrated circuit according to claim 2, wherein the first and second lateral contacts as well as the bit lines lie on a frontside of the memory cells, whereas the power distribution network spans at a backside of the memory cells.

4. The integrated circuit according to claim 2, wherein the first and second lateral contacts respectively extend across an interface shared by two adjacent ones of the memory cells.

5. The integrated circuit according to claim 2, wherein a plurality of the first lateral contacts are connected in parallel with a reference voltage transmitted through the power distribution network, and a plurality of the second lateral contacts are connected in parallel with a power supply voltage transmitted through the power distribution network.

6. The integrated circuit according to claim 1, wherein the memory cells are connected to the bit lines through third lateral contacts in between, and the third lateral contacts each extend through an interface shared by two adjacent ones of the memory cells.

7. The integrated circuit according to claim 6, wherein each third lateral contact is overlapped with two of the bit lines, but is connected to only one of the two overlapping bit lines.

8. The integrated circuit according to claim 1, wherein the pass-gate transistors are controlled by word lines running above all of the bit lines.

9. An integrated circuit, comprising:
memory cells, respectively comprising:
a first active structure and a second active structure, separately extending along a column direction; and
a first gate structure, a second gate structure, a third gate structure and a fourth gate structure, separately extending along a row direction and arranged in order along the column direction, to cover and intersect each of the first and second active structures, wherein N-type transistors comprising a first pass-gate transistor, a first pull-down transistor, a second pull-down transistor and a second pass-gate transistor are defined at intersections of the first active structure and the first to fourth gate structures respectively, and P-type transistors comprising a first pull-up transistor and a second pull-up transistor are defined at intersections of the second active structure and the first to fourth gate structures respectively;
bit lines, lying over and passing through the memory cells along the column direction, wherein the first pass-gate transistor in a first memory cell of the memory cells is connected to a first bit line of the bit lines which intersects the first memory cell, and the second pass-gate transistor in the first memory cell is connected to a second bit line of the bit lines which intersects a second memory cell of the memory cells that is next to the first memory cell; and
a power distribution network, powering the memory cells from below the memory cells.

10. The integrated circuit according to claim 9, wherein the first pass-gate transistor in the first memory cell is connected to the first bit line via a first lateral contact, and the second pass-gate transistor in the first memory cell is connected to the second bit line through a second lateral contact.

11. The integrated circuit according to claim 10, wherein the first and second lateral contacts extend across an interface shared by the first and second memory cells.

12. The integrated circuit according to claim 10, wherein the first pass-gate transistor in the second memory cell is also connected to the first bit line through the first lateral contact, and the second pass-gate transistor in the second memory cell is also connected to the second bit line through the second lateral contact.

13. The integrated circuit according to claim 10,
wherein the first bit line laterally protrudes along with the first lateral contact, with respect to a line portion of the first bit line, and
wherein the second bit line laterally protrudes along with the second lateral contact, with respect to a line portion of the second bit line.

14. The integrated circuit according to claim 10, wherein the first lateral contact is connected to the first bit line through a first via, and the second lateral contact is connected to the second bit line through a second via.

15. The integrated circuit according to claim 14,
wherein the first via laterally extends along the first lateral contact, beyond a lateral span of the first bit line, and
wherein the second via laterally extends along the second lateral contact, beyond a lateral span of the second bit line.

16. The integrated circuit according to claim 9, wherein a common source/drain terminal of the first pass-gate transistor and the first pull-down transistor as well as a source/drain terminal of the first pull-up transistor in each memory cell are connected through a third lateral contact, and a common source/drain terminal of the second pass-gate transistor and the second pull-down transistor as well as a source/drain terminal of the second pull-up transistor in each memory cell are connected through a fourth lateral contact.

17. The integrated circuit according to claim 16, wherein in each memory cell, the third lateral contact extending between the first and second gate structures is connected to the third gate structure through a first conductive line, and the fourth lateral contact extending between the third and fourth gate structures is connected to the second gate structure through a second conductive line.

18. The integrated circuit according to claim 16, wherein the first and fourth gate structures in each memory cell is connected through a third conductive line.

19. The integrated circuit according to claim 18, wherein the first, second and third conductive lines of the first memory cell and the first bit line are arranged in order along the row direction, and wherein the first conductive line of the second memory cell, the second bit line, the second conductive line of the second memory cell and the third conductive line of the second memory cell are arranged in order along the row direction.

20. An integrated circuit, comprising:
a power distribution network, comprising layers of power rails;
a first memory cell and a second memory cell next to each other, disposed on the power distribution network, wherein each of the first and second memory cells comprises:
a first active structure and a second active structure, respectively extending along and overlapping one of the power rails; and
a first gate structure, a second gate structure, a third gate structure and a fourth gate structure, covering and intersecting each of the first and second active structures, wherein N-type transistors comprising a first pass-gate transistor, a first pull-down transistor, a second pull-down transistor and a second pass-gate transistor are defined at intersections of the first active structure and the first to fourth gate structures, P-type transistors comprising a first pull-up transistor and a second pull-up transistor are defined at intersections of the second active structure and the first to fourth gate structures, the first and second pull-down transistors are connected to the power rail overlapped with the first active structure by a common source/drain terminal, and the first and second pull-up transistors are connected to the power rail overlapped with the second active structure by a common source/drain terminal; and
bit lines, lying over and crossing the memory cells, wherein the first pass-gate transistor in the first memory cell is connected to a first bit line of the bit lines which intersects the first memory cell, and the second pass-gate transistor in the first memory cell is connected to a second bit line of the bit lines which intersects the second memory cell.
